(19) United States
(12) Patent Application Publication
(10) Pub. No.: US 2020/0052378 A1
(43) Pub. Date: Feb. 13, 2020

(54) ANTENNA SYSTEM AND MOBILE TERMINAL

(71) Applicant: AAC Technologies Pte. Ltd., Singapore city (SG)

(72) Inventors: Shijie Liu, Shenzhen (CN); Yongli Chen, Shenzhen (CN); Yue Liang, Shenzhen (CN)

(21) Appl. No.: 16/524,073

(22) Filed: Jul. 28, 2019

(30) Foreign Application Priority Data
Aug. 13, 2018 (CN) 201810917496.7

(51) Int. Cl. H01Q 1/24; H01Q 21/06; H04B 7/0413

(52) U.S. Cl. CPC H01Q 1/243; H03F 3/213; H04B 7/0413; H01Q 21/065

(57) ABSTRACT

The present disclosure provides an antenna system applied to a mobile terminal. The mobile terminal includes: a housing; a main board received in the housing and including a power amplifier; a plurality of antenna units; and a transmission circuit board received in the housing and configured to electrically connect the power amplifier with the plurality of antenna units. The transmission circuit board includes a plurality of transmission lines configured to feed the plurality of antenna units with power. Compared with the related art, the antenna system provided by the present disclosure, by additionally providing a transmission circuit board dedicated to connecting a power amplifier with an antenna unit, eliminates the necessity of routing on a main board to connect the power amplifier with the antenna unit, so as to facilitate wire arrangement and avoid signal interference between the respective traces.

### TECHNICAL FIELD

The present disclosure relates to the field of antenna technologies, and in particular, to an antenna system and a mobile terminal.

### BACKGROUND

In wireless communication devices, there is always a device that radiates electromagnetic energy into space and receives electromagnetic energy from space, and this device is an antenna. The role of the antenna is to transmit a digital or analog signal modulated onto a radio frequency (RF) frequency to a spatial wireless channel, or to receive a digital or analog signal modulated onto a RF frequency from a spatial wireless channel.

Nowadays, the 5G communication technology is booming. Multiple-Input Multiple-Output (MIMO) technology is the core technology of 5G antennas, and regarding to the 8×8 MIMO antenna of sub-6G, routing of transmission lines between a PA (power amplifier) and an antenna feeding point is noteworthy. In the related art, one PA is routed to the antenna feeding point through traces on a PCB board. Multiple antennas have multiple transmission lines from the PA to the antenna feeding point. The drawback lies in that a layout of a main board is compact, making it difficult to lay out multiple routing wires concurrently, and that interference with other signal lines exists, resulting in the demand to solve the interference problem.

Therefore, it is necessary to provide a novel antenna system to solve the above problems.

### BRIEF DESCRIPTION OF DRAWINGS

Many aspects of the exemplary embodiment can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a structural block diagram of an antenna system according to the present disclosure;

FIG. 2 is a structural schematic diagram of a mobile terminal according to the present disclosure;

FIG. 3 is a partial structural schematic diagram of a transmission circuit board according to the present disclosure;

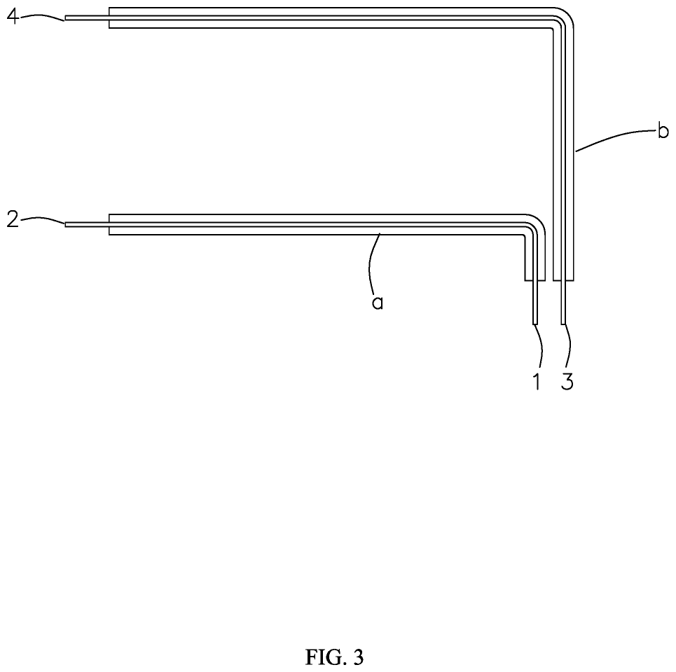

FIG. 4 is a reflection coefficient diagram of two transmission lines in FIG. 3; and

FIG. 5 is a transmission coefficient diagram of two transmission lines in FIG. 3.

### DESCRIPTION OF EMBODIMENTS

The present disclosure will be further illustrated with reference to the accompanying drawings and the embodiments.

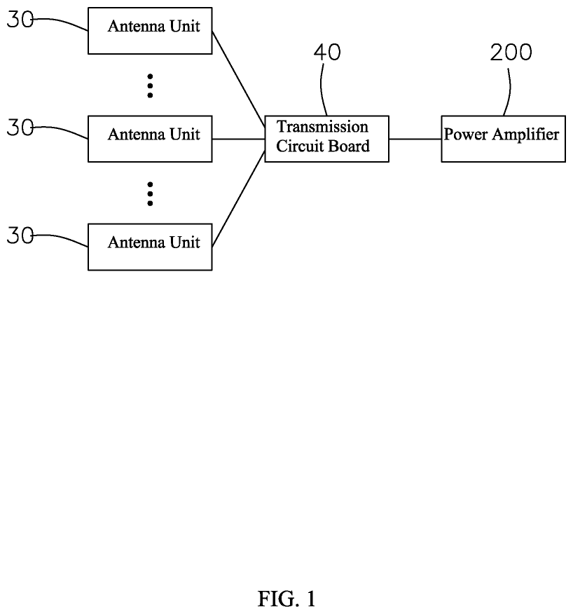

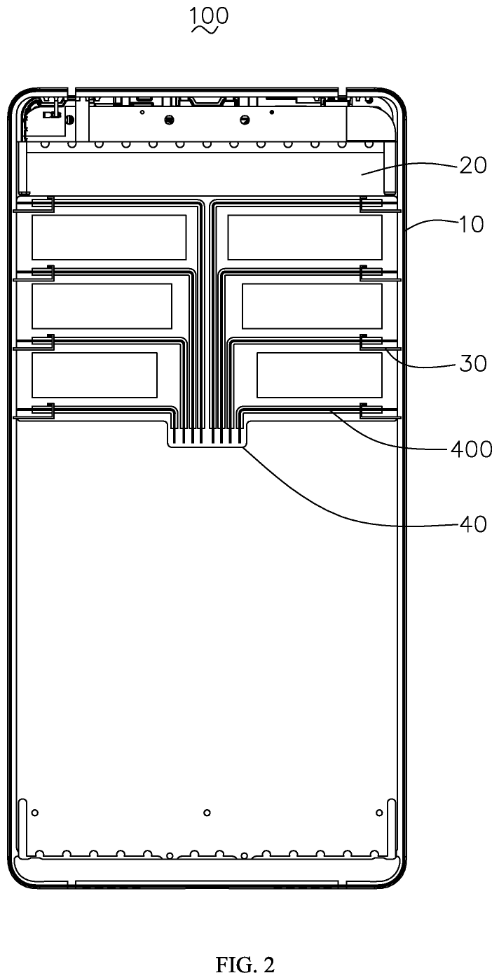

Referring to FIG. 1 and FIG. 2, an embodiment of the present disclosure provides an antenna system, which has operating bands of 3.4-3.6 GHz and 4.8-5.0 GHz and is applied to a mobile terminal 100. The mobile terminal 100 includes a housing 10, a main board 20, an antenna unit 30, and a transmission circuit board 40. The main board 20, the antenna unit 30, and the transmission circuit board 40 are all received in the housing 10.

The housing 10 may be made of a non-metallic material, and at least, a portion of the housing 10 facing right towards a signal radiation direction of the antenna unit 30 is made of a non-metallic material, thereby reducing the electromagnetic shielding effect on the antenna unit 30. In a preferred embodiment of the disclosure, the housing 10 is made of plastic.

The main board 20 includes a power amplifier 200. The main board 20 may further include a feeding network (not shown) matching with the power amplifier 200.

There are multiple antenna units 30 provided, so as to achieve a Multiple-Input Multiple-Output function.

The transmission circuit board 40 is an FPC transmission circuit board or an LCP transmission circuit board, for electrically connecting the power amplifier 200 with the antenna unit 30. The transmission circuit board 40 includes multiple transmission lines 400 that feed the antenna unit 30 with power. One end of each of the multiple transmission lines 400 is gathered together to be connected to the power amplifier 200, and the other ends thereof are separated so as to be connected to the multiple antenna units 30.

In a specific embodiment provided by the present disclosure, the antenna system includes eight antenna units 30 and eight transmission lines. The eight antenna units 30 are symmetrically arranged in an array with respect to a center line of the mobile terminal, and the eight transmission lines 400 are respectively symmetrically arranged in an array with respect to the center line of the mobile terminal.

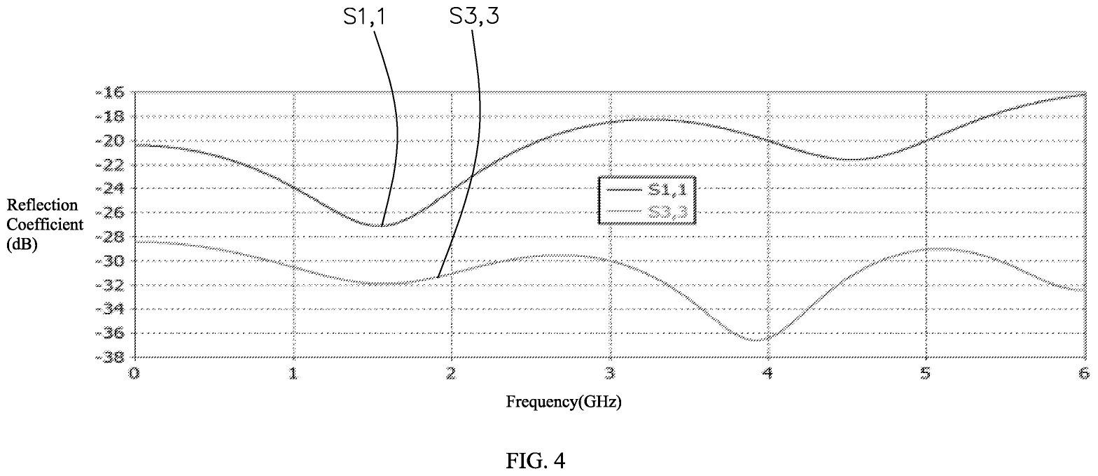

Referring to FIG. 4 in conjunction, two transmission lines 400 are taken as samples for conducting reflection coefficient tests on the transmission line 400 provided by the present disclosure, and these two transmission lines are labeled as a and b, respectively. One end of the transmission line a connected to the power amplifier 200 is labeled as 1, and the other end thereof connected to the antenna unit 30 is labeled as 2; one end of the transmission line b connected to the power amplifier 200 is labeled as 3, and the other end thereof connected to the antenna unit 30 is labeled as 4.

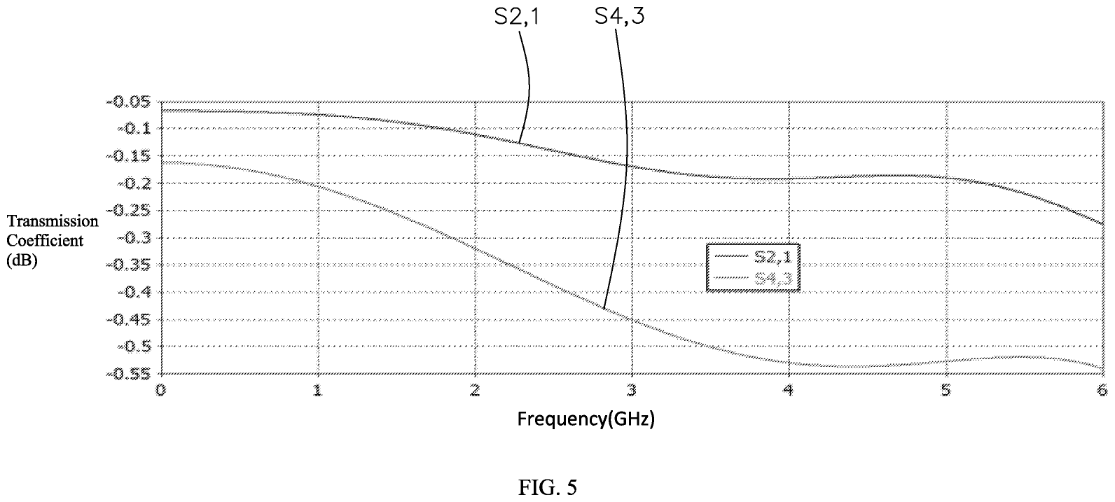

Referring to FIG. 5, from S1,1, S3,3 that are respectively reflection coefficient curves of the transmission lines a and b and S2,1, S4,3 that are respectively transmission coefficient curves of the transmission lines a and b, it can be seen that the transmission line has the performance of a small transmission loss in the operating bands of the antenna system of 3.4-3.6 GHz and 4.8-5.0 GHz, which can meet actual demands.

The present disclosure provides a mobile terminal 100 including the antenna system described above.

Compared with the related art, the antenna system provided by the present disclosure, by additionally providing a transmission circuit board dedicated to connecting a power amplifier with an antenna unit, eliminates the necessity of routing on a main board to connect the power amplifier with the antenna unit, so as to facilitate the arrangement of traces and avoid the signal interference between the respective traces.

What has been described above is only an embodiment of the present disclosure, and it should be noted herein that one ordinary person skilled in the art can make improvements without departing from the inventive concept of the present disclosure, but these are all within the scope of the present disclosure.

What is claimed is:

1. An antenna system applied to a mobile terminal, the mobile terminal comprising:
a housing;
a main board received in the housing and comprising a power amplifier;
a plurality of antenna units; and
a transmission circuit board received in the housing and configured to electrically connect the power amplifier with the plurality of antenna units, the transmission circuit board comprising a plurality of transmission lines configured to feed the plurality of antenna units with power.

2. The antenna system as described in claim 1, wherein the antenna system has operating bands of 3.4-3.6 GHz and 4.8-5.0 GHz.

3. The antenna system as described in claim 1, wherein the transmission circuit board is an FPC transmission circuit board or an LCP transmission circuit board.

4. The antenna system as described in claim 1, wherein one end of each of the plurality of transmission lines is gathered together to be connected to the power amplifier, and the other ends thereof are separated so as to be connected to the plurality of antenna units.

5. The antenna system as described in claim 3, wherein one end of each of the plurality of transmission lines is gathered together to be connected to the power amplifier, and the other ends thereof are separated so as to be connected to the plurality of antenna units.

6. The antenna system as described in claim 4, wherein the plurality of antenna units comprises eight antenna units forming an 8×8 MIMO antenna system.

7. The antenna system as described in claim 5, wherein the plurality of antenna units comprises eight antenna units forming an 8×8 MIMO antenna system.

8. The antenna system as described in claim 6, wherein the eight antenna units are symmetrically arranged in an array with respect to a center line of the mobile terminal, and the plurality of transmission lines comprises eight transmission lines symmetrically arranged in an array with respect to the center line of the mobile terminal.

9. The antenna system as described in claim 7, wherein the eight antenna units are symmetrically arranged in an array with respect to a center line of the mobile terminal, and the plurality of transmission lines comprises eight transmission lines symmetrically arranged in an array with respect to the center line of the mobile terminal.

10. A mobile terminal, comprising the antenna system as described in claim 1.
